(19) United States
(12) Patent Application Publication
(10) Pub. No.: US 2011/0267133 A1
(43) Pub. Date: Nov. 3, 2011

(54) CURRENT GENERATING CIRCUIT

(76) Inventor: Ajay Kumar, Dallas, TX (US)

(21) Appl. No.: 12/770,838

(22) Filed: Apr. 30, 2010

(51) Int. Cl. H03L 5/00

(52) U.S. Cl. 327/512

(57) ABSTRACT

A current generating circuit including a current mirror, an impedance device, a first voltage generating portion and a second voltage generating portion. The current mirror has a current output leg and a current generating leg. The impedance device is connected to the current generating leg. The first voltage generating portion can generate a first voltage that is complementary to absolute temperature. The second voltage generating portion can generate a second voltage that is proportional to absolute temperature. The first voltage generating portion and the second voltage generating portion are arranged to generate an impedance current across the impedance device. The current output leg is operable to output an output current based on the impedance current. The impedance device has an impedance value, a first terminal and a second terminal. An impedance voltage drop across the first terminal and the second terminal is equal to a product of the impedance value and the impedance current. The first voltage is based on an attenuation of the impedance voltage drop.

### BACKGROUND

Integrated circuits have a widespread use and are a crucial component in today's technologies. There are many important factors to consider when designing integrated circuits. These factors include but are not limited to the accuracy, power consumption, total area and the turn on time. Accuracy is measured as a percentage, which in one example may he expressed as the variation of the actual current output compared to the desired current output. Together these factors can be used to express a figure of metric (FOM). The lower the FOM the better it is. This is based on the fact that integrated circuits with greater accuracy (lower percentage variation), lower power consumption, lower turn on time and occupying a smaller area are more desirable.

One particular circuit that may be implemented on an integrated circuit is a current reference circuit. FIG. 1 illustrates a prior art current reference circuit 100.

Current reference circuit 100 includes a voltage source 102, a differential amplifier 104, a transistor 106, a resistor 108, a ground 110, a current mirror 112 and an output current port 114.

Voltage source 102 provides an input voltage, which may also be considered a bandgap voltage, to the positive input of differential amplifier 104. Voltage source 102 has a temperature coefficient and, presume for purposes of discussion, in this example is generally equivalent to 1.2 volts. The output of differential amplifier 104 is fed into the gate of transistor 106. The source of transistor 106 is connected to the negative input of differential amplifier 104 and to resistor 108. In this example, resistor 108 is an n-well resistor but may be alternatively implemented as any known impedance device, such as a switched-capacitor circuit or other type of impedance supported by the process. Resistor 108 is attached to ground 110. The drain of transistor 106 is connected to current mirror 112.

Differential amplifier 104 along with device 106 act as a buffer to generate a voltage across resistor 108. The voltage across resistor 108 generates a resulting current that current mirror 112 mirrors at output current port 114.

The output current at output current port 114 can be either equal to the current through resistor 108 or a multiple of it. In this example, resistor 108 has a temperature coefficient as n-well resistors typically have large temperature coefficients. The temperature coefficient of the output current at output current port 114 is equal to the inverse of the temperature coefficient of resistor 108. Alternatively, the standard deviation of the temperature coefficient of the output current at output current port 114 is equivalent to the sum of the standard deviation of the temperature coefficient of voltage source 102 and the standard deviation of the temperature coefficient of resistor 108.

As a result of the temperature coefficients of resistor 108 and voltage source 102, the output current at output current port 114 varies across temperature variation. This is a problem as output current is often desired to be stable or follow a fixed desired pattern (e.g., often a PTAT current is desired for a constant Gm circuit'or amplifiers).

As mentioned above, resistor 108 may be alternatively implemented as a switched-capacitor circuit. A switched-capacitor circuit alleviates some of the temperature coefficient issues but introduces new concerns. A switched-capacitor circuit requires a clock frequency that causes spurs in the current, and therefore provides a less stable output current. These spurs are not desirable in most application and can be filtered but not entirely eliminated. But the current will still have the process variation of the capacitors.

Some electronic devices contain circuitry having a complementary to absolute temperature (CTAT) nature or having a proportional to absolute temperature (PTAT) nature. The voltage across circuitry having a CTAT nature falls when temperature rises and the voltage rises when temperature falls. The voltage across circuitry having a PTAT nature rises when temperature rises and the voltage falls when temperature falls. Some electronic devices may contain both CTAT and PTAT circuitry. As a result of CTAT and PTAT aspects of a circuit, the output current may be some of the two currents and may vary or be constant as temperature varies during operation. It may be important to have a constant output current. Specifically, operational amplifiers are particularly delicate and any current variation across these devices may result in distortion or errors in the circuit.

A conventional manner to address temperature variation in a constant current provider will now be described with reference to FIG. 2.

FIG. 2 illustrates a conventional bandgap circuit 200.

Bandgap circuit 200 includes a voltage source 202, transistors 204 and 206, nodes 208 and 210, resistor 212, transistor 214, differential amplifier 216, resistors 218 and 220 and transistor 222.

Voltage source 202 provides an input supply voltage to the source of transistors 204 and 206. The drain of transistor 204 is fed to node 208, and the drain of transistor 206 is fed to node 210. The currents from the source of transistor 204 and 206 are equivalent, and for purposes of discussion, equal 100 μA. Node 208 is connected to resistor 212, transistor 214 and the negative input of differential amplifier 216. Node 210 is connected to resistors 218 and 220 as well as the positive input of differential amplifier 216. The output of differential amplifier 216 is connected to the gates of transistors 204 and 206.

Resistor 218 is connected to transistor 222. Resistors 212 and 220 as well as transistors 214 and 222 are all connected to a ground 224. Transistors 222 often contains multiple fingers of 214. As a result, transistor 222 requires less gate to source voltage over-drive then transistor 214 when the same amount of current is applied.

Equivalent currents are fed into nodes 208 and 210. This produces voltages having a CTAT nature across resistors 212 and 220. This is due to the fact that the emitter to base voltage transistors 214 and 222 have negative temperature coefficients. A voltage drop across a diode has a negative temperature coefficient because the voltage across a diode falls as the temperature increases.

Differential amplifier 216 holds equal voltages at nodes 208 and 210. For purposes of discussion, presume in this example that this voltage is 800 mV and therefore the voltage across transistor 214 is 800 mV. Consequently the voltage across transistor 222 could be 700 mV and the voltage across resistor 218 could be 100 mV. The voltage drop across resistor 218 is of a PTAT nature and grows as temperature rises. The currents across resistors 218 and 220 are summed at node 210 and are ideally equal to the currents from the sources of transistors 204 and 206. Inequality amongst the currents across resistors 218 and 220 is caused by the mistmatch in transistors 204 and 206 and it results in output current variation across temperature.

The voltage across resistor 218 may be multiplied by a constant and added to the voltage across transistor 214 in order to attempt to provide a constant voltage across varying temperature. An attempt to create a constant current source can then be derived from the constant voltage.

Bandgap circuit 200 addresses the issue of a varying current resulting from a varying temperature by generating an amount of CTAT voltage that will address variation caused by the PTAT generated voltage. Ideally the CTAT generated voltage will complement the PTAT generated voltage in order to output a constant current.

Bandgap circuit 200 is an improvement over circuit 100 but still has drawbacks. In some bandgap circuits, a PTAT voltage is amplified and added to a voltage (V_{BE}) between a base and an emitter of a transistor to obtain a bandgap voltage for an example anywhere between 0.8 to 1.4V. This is done in an open loop fashion, which reduces the accuracy. Additionally, a large current variation occurs when dropping voltage across a resistor in order to generate current, as shown in current reference circuit 100. In addition, a bandgap voltage of 1.2 volts puts a lower limit on the supply voltage. Several applications require a current with a much lower supply voltage. Lastly, several applications may be subject to an automotive environment, where temperature may vary from −55° Celsius to 155° Celsius. In this temperature range, circuits configured similarly to the circuits shown in FIG. 1 and FIG. 2 output varying currents as will be shown in FIG. 9.

What is needed is a circuit that provides a more accurate output current as temperature varies.

### BRIEF SUMMARY

The present invention provides a system and method for providing a more accurate output current in the face of varying temperature.

In accordance with an aspect of the present invention, a current generating circuit is provided that includes a current mirror, an impedance device, a first voltage generating portion and a second voltage generating portion. The current mirror has a current output leg and a current generating leg. The impedance device is connected to the current generating leg. The first voltage generating portion can generate a first voltage that is complementary to absolute temperature. The second voltage generating portion can generate a second voltage that is proportional to absolute temperature. The first voltage generating portion and the second voltage generating portion are arranged to generate an impedance current across the impedance device. The current output leg is operable to output an output current based on the impedance current. The impedance device has an impedance value, a first terminal and a second terminal. An impedance voltage drop across the first terminal and the second terminal is equal to a product of the impedance value and the impedance current. The first voltage is based on an attenuation of the impedance voltage drop.

Additional advantages and novel features of the invention are set forth in part in the description which follows, and in part will become apparent to those skilled in the art upon examination of the following or may be learned by practice of the invention. The advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate an exemplary embodiment of the present invention and, together with the description, serve to explain the principles of the invention. In the drawings:

FIG. 1 illustrates a prior art current reference circuit;

FIG. 2 illustrates a classic bandgap circuit of the prior art;

FIG. 3 illustrates an example of a constant current generating circuit in accordance with an aspect of the present invention;

FIG. 4 illustrates another example of a constant current generating circuit in accordance with an aspect of the present invention;

FIG. 5 illustrates the unity gain amplifier from the constant current generating circuit of FIG. 4 as an arrangement of transistors;

FIG. 6 illustrates the differential amplifier from the constant current generating circuit of FIG. 4 as an arrangement of transistors;

FIG. 7 shows a graph of current and voltage varying across a resistor from FIG. 4 as temperature varies compared to ideal results;

FIG. 8 shows a graph of current across a resistor from FIG. 4 as temperature increases including the variation in the resistance of the resistor; and

FIG. 9 shows a graph of the output current of a current reference circuit including a switched-capacitor circuit as temperature increases.

### DETAILED DESCRIPTION

A signal generating circuit in accordance with aspects of the present invention provides a more constant output signal than conventional signal generating circuits in the face of varying temperature. In example embodiments, a constant output signal is provided in the face of varying temperature by generating a PTAT voltage and a CTAT voltage, attenuating the CTAT voltage, and adding the attenuated CTAT voltage to the PTAT voltage in a closed-loop circuit.

As discussed above in the prior art, a PTAT voltage was previously amplified to obtain a bandgap voltage. This enables a circuit in accordance with the present invention to generate sub-1V bandgap voltage/current reference and ultra low voltage operation. Instead of amplifying a PTAT voltage, in accordance with aspects of the present invention, a voltage from a base of a transistor to the emitter of the transistor, V_{BE}, is attenuated to generate a bandgap voltage. The generated bandgap voltage is used to generate a bandgap current, which follows a resistor temperature coefficient as shown in equation (1):

ΔV_{BE}+ηV_{BE}=I_{REF}R(1+αT) (1)

Here ΔV_{BE} is the difference between V_{BE} at a first transistor and at a second transistor, η is an attenuation factor, I_{REF} is the output current, R is a resistance of a resistor, α is the resistor temperature coefficient of the resistor and T is the temperature in Kelvin. Equation (1) can be alternatively written as equation (2) shown below:

V_{BE1}+ηV_{BE}−V_{BE2}=1_{REF}R(1+αT) (2)

The left side of equation (2) can be split into a PTAT voltage and a CTAT voltage portion as shown in equation (3):

$$\frac{kT}{q} ln ( \frac{{A}_{1} {I}_{2}}{{A}_{2} {I}_{1}} ) + \frac{{R}_{1}}{{R}_{1} + {R}_{2}} {V}_{BE} = {I}_{REF} {R}_{0} ( 1 + α T ) \qquad ( 3 )$$

The PTAT voltage portion of equation (3) is the product of the natural log of the ratio of (A₁I₂ and A₂I_{1) and kT/q. A}₁ is the area of the first transistor and A₂ is the area of the second transistor. I₁ is the current across the first transistor and I₂ is the current across the second transistor. T is temperature in Kelvin, with k being the Boltzmann constant and q equaling one electron charge.

The CTAT voltage portion of equation (3) is the product of V_{BE} and a resistive or impedance divider R₁/(R₁+R₂), where R₁ is a first resistor and R₂ is a second resistor. The resistive divider provides the attenuation factor.

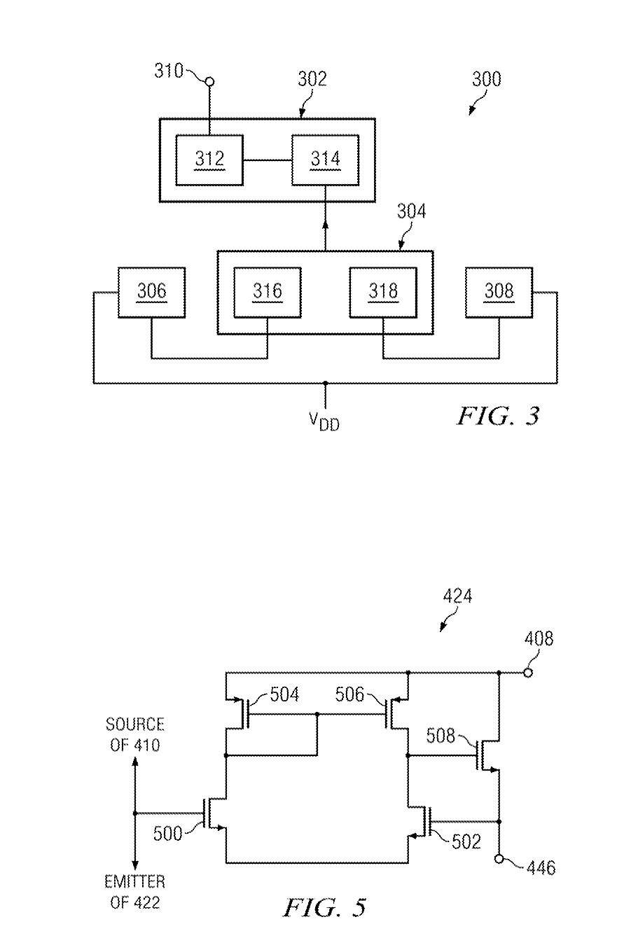

Equation (3) provides the basis for aspect of the present invention. An example embodiment of the present invention will now be described with reference to FIG. 3.

FIG. 3 shows an example current generating circuit 300 in accordance with an aspect of the present invention.

Current generating circuit 300 includes a current mirror 302, an impedance device 304, a first voltage generating portion 306, a second voltage generating portion 308 and a current output port 310. Current mirror 302 includes a current output leg 312 and a current generating leg 314. Impedance device 304 has an impedance value and includes a first terminal 316 and a second terminal 318.

Current generating leg 314 is connected to current output leg 312 and to impedance device 304. First voltage generating portion 306 is connected to first terminal 316. Second voltage generating portion 308 is connected to second terminal 318. A supply voltage V_{DD} is connected to both first voltage generating portion 306 and second voltage generating portion 308.

First voltage generating portion 306 is configured to generate a CTAT voltage. As discussed above, a CTAT voltage has an inverse relationship with temperature. Second voltage generating portion 308 is configured to generate a PTAT voltage. As discussed above, a PTAT voltage follows any change in temperature. First voltage generating portion 306 and second voltage generating portion 308 are arranged to generate impedance current across impedance device 304 to current generating leg 314. Any change in temperature causes the PTAT voltage to change along with the CTAT voltage. Ideally these changes in CTAT and PTAT voltages complement each other and result in the impedance current being constant.

Current output leg 312 is configured to output an output current at current port 310 that is based on the impedance current. In one exemplary embodiment, the output current at current port 310 is 30 times the impedance current.

An impedance voltage drop Vᵢ across first terminal 316 and second terminal 318 is determined as follows:

VᵢI•Z, (4)

where Z is the impedance value of impedance device 304 and I is the impedance current across impedance device 304 to current generating leg 314. First voltage generating portion 306 is based on an attenuation of the impedance voltage drop Vᵢ.

First voltage-generating portion 306 may include an impedance divider. In an example embodiment, the impedance divider includes a first resistor and a second resistor. In another example embodiment a closed loop differential amplifier may also be connected to the first resistor.

Second voltage-generating portion 308 may include a differential amplifier and a translinear loop. In an example embodiment, the translinear loop may include a transistor that has a base connected to the first and second resistors of first voltage-generating portion 306.

Impedance device 304 may be any known impedance device, non-limiting examples of which include resistors, capacitors, inductors, diodes, switch capacitor, switch current and combinations thereof. In an example embodiment, impedance device includes a resistor, where the resistor may be trimable or variable.

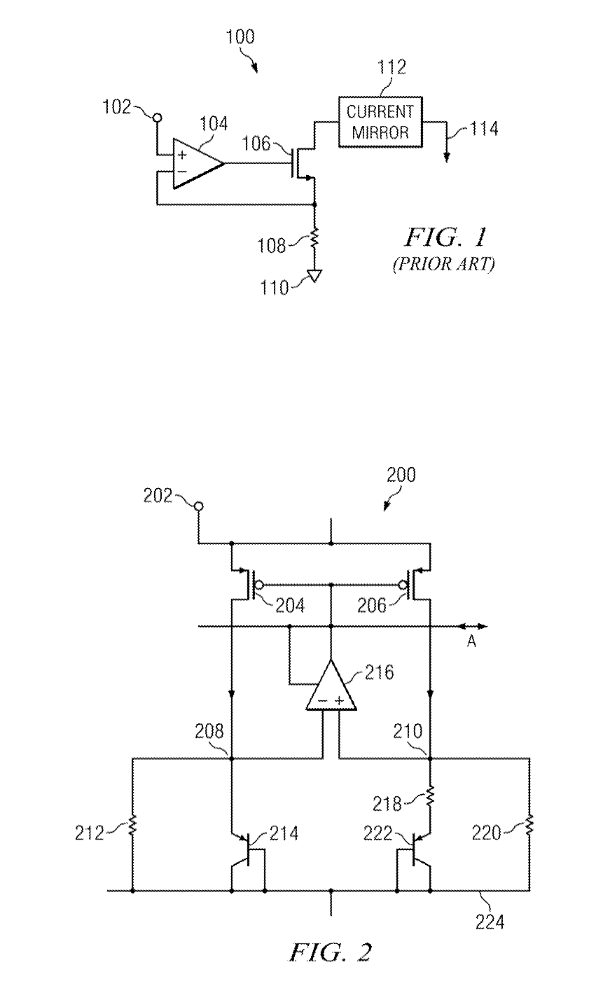

As opposed to the conventional constant current provider circuits discussed in FIGS. 1 and 2, circuit 300 does not require an outside reference voltage source. Current port 310 provides constant current based on the impedance current provided by impedance device 304.

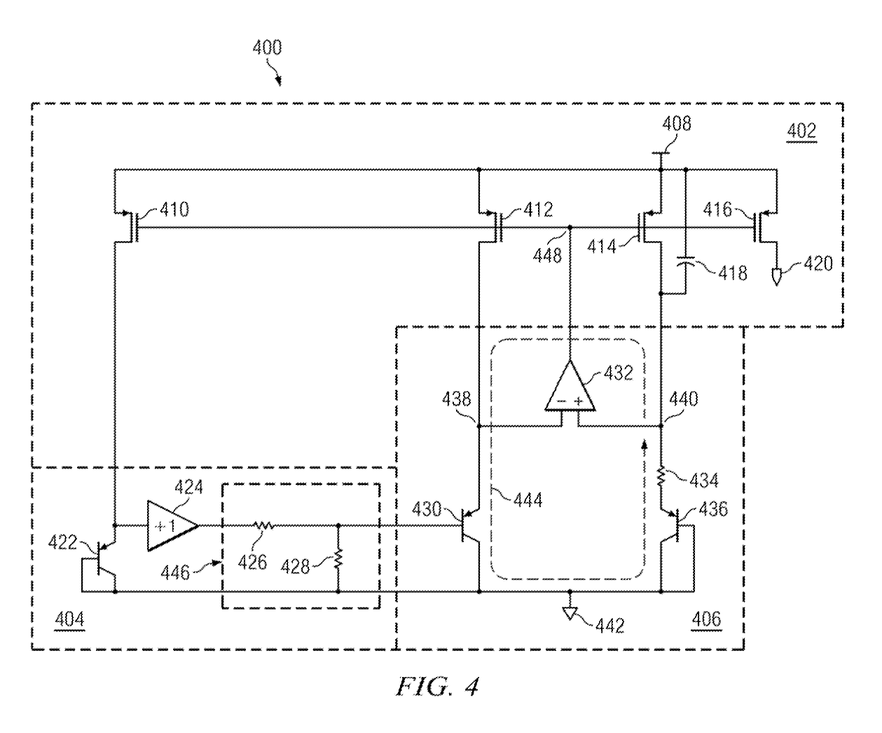

A more detailed example circuit in accordance with an aspect of the present invention will now be described with reference to FIG. 4.

FIG. 4 illustrates an example current generating circuit 400 in accordance with an aspect of the present invention.

As illustrated in the figure, current generating circuit 400 includes a current output portion 402, a fractional CTAT voltage generating portion 404 and a PTAT voltage generating portion 406. Current output portion 402 includes a voltage source 408, transistors 410, 412, 414 and 416, a capacitor 418 and an output current port 420. Fractional CTAT voltage generating portion 404 includes a transistor 422, a unity gain amplifier 424 and resistors 426 and 428. PTAT voltage generating portion 406 includes a transistor 430, a differential amplifier 432, a resistor 434 and a transistor 436.

With reference to equation (3), the configuration of transistors 412, 414, 430 and 436 are chosen so the resultant temperature coefficient of the voltage across resistor 434 is nearly the same as the resistor temperature coefficient of resistor 434, so that it results in an near zero temperature coefficient for current from resistor 434 and output port 420. Transistor 412 is configured to carry a current 3 times greater than the current through transistor 414. Transistor 430 is configured as one diode and transistor 436 is configured as ten diodes. This allows for the PTAT voltage across resistor 434 to be roughly equivalent to 100 mV as will be shown below:

(kT)/(q)*1n(A₁I₂)/(A₂I₁)=ΔV_{BE} (5)

Here ΔV_{BE} is equal to the voltage across resistor 434. For purposes of the discussion presume that:

(kT)/(q)≈mV (6)

Further, presume that the area of Transistor 436 is ten times larger than Transistor 430, since transistor 436 is made up of ten diodes and transistor 430 is made up of only one diode. Additionally, presume that the current through transistor 412 is three times greater than the current through transistor 414. In such a case:

(A₁I₂)/(A₂I₁)=(10*3)/(1*1)=30 (7)

Plugging in equations (6) and (7) into equation (5) solves for ΔV_{BE}:

26*1n(30)≈100 mV=ΔV_{BE} (8)

The voltage ΔV_{BE} is the voltage across resistor 434 and has a PTAT nature, meaning that the voltage rises when temperature rises and the voltage falls when temperature falls. With reference to equation (3) discussed above, this PTAT voltage is added to a CTAT voltage to obtain a constant current I_{REF}. The factors of the CTAT voltage are shown below:

V_{BE}•(R₁/(R₁+R₂)) (9)

The factors of the CTAT voltage are chosen such that the I_{REF} current is equal to 5 μA, which is a desired input current for the operation of many integrated circuits.

The current across resistor 434 should ideally be constant even in the face of a change in temperature. If the current across resistor 434 is constant in the face of a change in temperature, then the currents across transistors 410, 412, 414 and 416 are also constant since these transistors form a current mirror.

Voltage source 408 provides an input supply voltage into the sources of transistors 410, 412, 414, 416 and capacitor 418. The drain of transistor 410 is connected to the emitter of transistor. 422 and to unity gain amplifier 424. The output of unity gain amplifier 424 is connected to resistor 426. Resistor 426 is connected to the base of transistor 430 and to resistor 428.

The emitter of transistor 430 is connected to the negative input of differential amplifier 432 and to the drain of transistor 412 at a node 438. The positive input of differential amplifier 432 is connected to resistor 434, capacitor 418 and the source of transistor 414 at a node 440. Resistor 434 is connected to the emitter of transistor 436. The output of differential amplifier 432 is fed into the gates of transistors 410, 412, 414 and 416. The drain of transistor 416 provides an output current at output current port 420.

The base and collector of transistors 422 and 436 are fed to a ground 442 as well as to resistor 428 and the collector of transistor 430.

The configuration of transistor 430, transistor 436, resistor 434 and amplifier 432 make up a translinear loop 444.

Capacitor 418 compensates the differential amplifier and the entire reference generating circuit to prevent them from oscillation. In this embodiment it is chosen to connect from VDD or voltage source 408 to improve the positive power supply rejection (PSR). This capacitor connection can be switched from node 440 to GND to improve negative supply rejection ration if application demands for it. The high PSR provides a constant current, which has immunity to the supply noise.

In CTAT voltage generating portion 404, the voltage across transistor 422 is buffered across unity gain amplifier 424. Unity gain amplifier 424 allows for the current from transistor 410 to flow through transistor 422 and not through resistors 426 and 428. Unity gain amplifier 424 prevents any further current variation to occur. The output voltage of unity gain amplifier 424 is then attenuated via resistors 426 and 428, arranged as an impedance divider 446. Here impedance divider 446 includes resistors 426 and 428, but may be alternatively embodied as including but not limiting to inductors, capacitors, diodes and switch capacitors: This attenuated voltage is equal to a fractional CTAT voltage and is fed into the base of transistor 430. This attenuated voltage is equivalent to ηV_{BE} shown in equation (2) above.

In PTAT voltage generating portion 406, transistor 430 acts like an emitter follower circuit with the voltage at node 438 equal to the sum of ηV_{BE} and V_{BE1}, where V_{BE1} is the emitter to base voltage drop across transistor 430. Differential amplifier 432 maintains equality of the voltages at nodes 438 and 440 to ηV_{BE}+V_{BE1}. The emitter of transistor 436 is at voltage V_{BE2}. The output of differential amplifier 432 is connected to the gates of transistors 412 and 414 at node 448. The voltage across resistor 434 is therefore equal to ηV_{BE}+V_{BE1}−V_{BE2}. The voltage ηV_{BE} is CTAT and the voltage V_{BE1}−V_{BE2} is a PTAT voltage. The current across resistor 434 is tied to transistor 414. Transistor 416 is the output leg of current output portion 402 and draws the same amount of current as transistor 414. In this case, the output current at output current port 420 is equal to the current across resistor 434. Alternatively the output current at output current port 420 may be a factor of the current through resistor 434.

Resistor 434 may be alternatively embodied as a variable or trimable resistor. When embodied as a trimable resistor with a 20% trim option for a 1 KΩ resistor, resistor 434 may have 20 Ω steps of resistance spanning from 800 Ω to 1.2 KΩ.

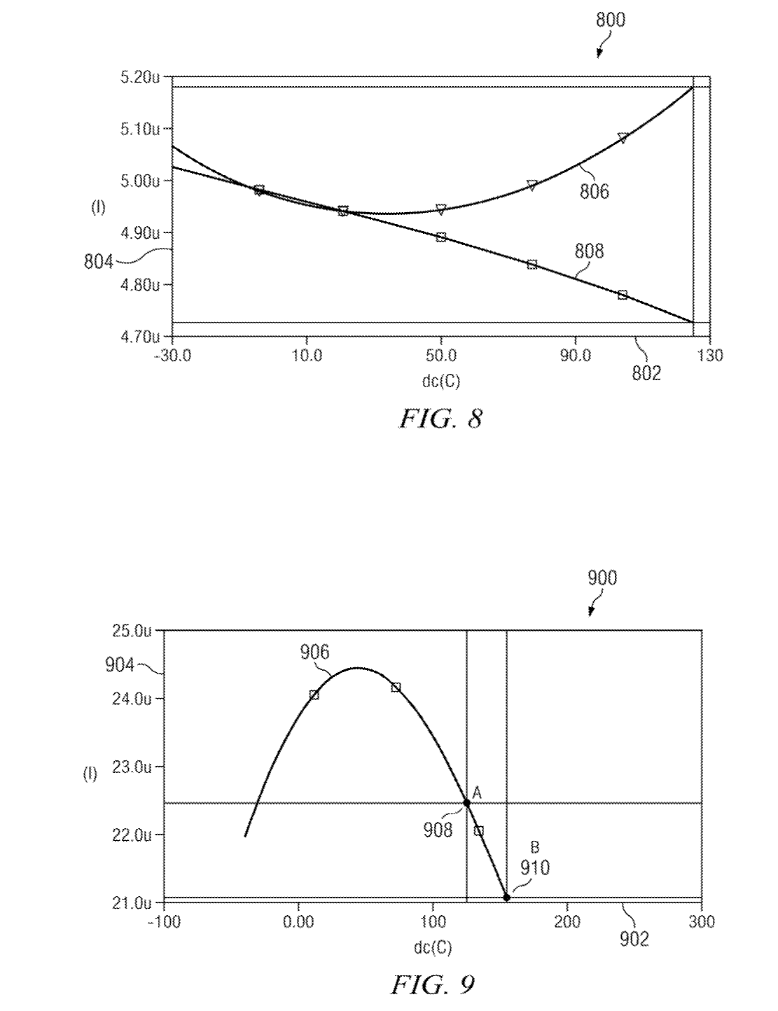

As discussed above, the output current at output current port 420 of circuit 400 is more stable than the conventional systems as discussed with reference to FIGS. 1 and 2. This will be described later in detail with reference to FIGS. 8 and 9.

In example embodiments, portions of circuit 400 may be implemented as transistors. FIG. 5 illustrates an example unity gain amplifier 424, of FIG. 4, as an arrangement of transistors, in accordance with an aspect of the present invention.

FIG. 5 shows gains Of one example of amplifier 424 embodied as an arrangement of transistors. It should he noted any other unity gain amplifier configuration may be used.

Unity gain amplifier 424 includes transistors 500, 502, 504, 506 and 508.

The gate of transistor 500 is connected to the drain of transistor 410 and the emitter of transistor 422. The source of transistor 500 is connected to the source of transistor 502. The drain of transistor 500 is connected to the drain of transistor 504. The gate of transistor 504 is connected to the gate of transistor 506 and is also connected to the drain of transistor 500. The drain of transistor 506 is connected to the gate of transistor 508 and is also connected to the drain of transistor 502. The source of transistor 508 is connected to the gate of transistor 502 and is also connected to impedance divider 446. The drains of transistors 504, 506 and 508 are all connected to supply voltage source 408.

Transistors 500 and 502 are configured to act as inputs of a differential amplifier, transistors 504 and 506 are configured to act as loads and transistor 508 is configured to act as the output-stage of a differential amplifier. Voltage at the emitter of transistor 422 generated by the current from the source of transistor 410, which is fed into the gate of transistor 500. Current from transistor 500 flows to transistors 502, 504 and 506. The drain of transistor 502 and 506 is the high impedance node of the amplifier. The amplified input error signal appears at this node which is fed into the output stage formed by device 508. Current from transistor 508 flows to impedance divider 446 and the voltage generated by the current is fed back to back to transistor 502 as a feedback signal to the close-loop unity gain amplifier.

As discussed above with respect to FIG. 5, unity gain amplifier 424 acts as a buffer to prevent current variation caused by the current sharing between transistor 502 and impedance divider 446.

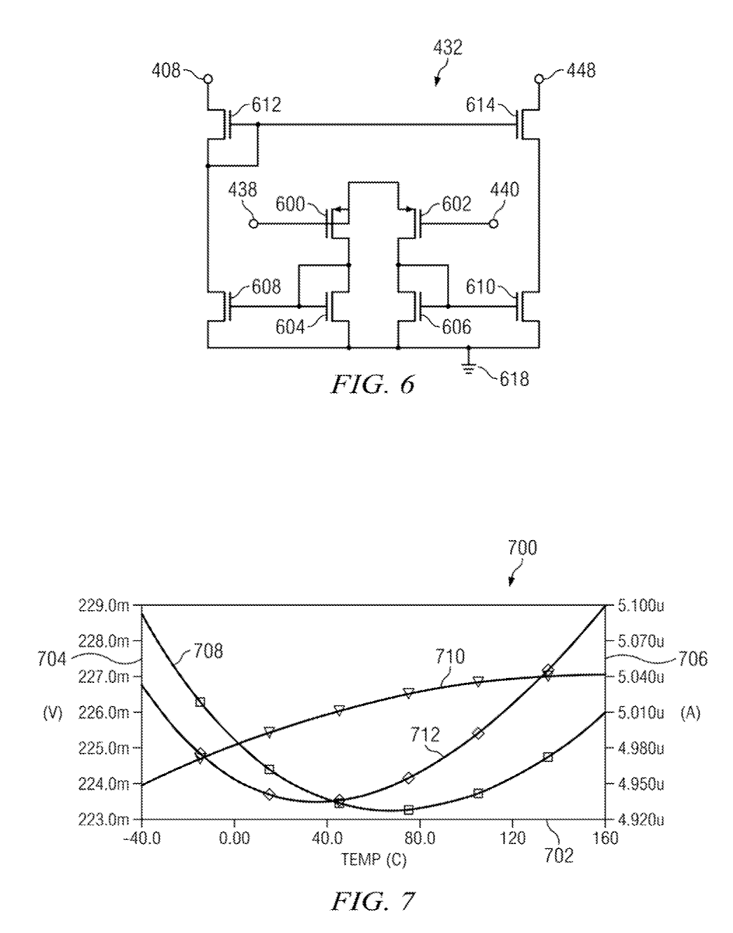

FIG. 6 illustrates an example differential amplifier 432, of FIG. 4, as an arrangement of transistors, in accordance with an aspect of the present invention.

Differential amplifier 432 includes transistors 600, 602, 604, 606, 608, 610, 612 and 614.

The gate of transistor 600 is connected to node 438. The source of transistor 600 is connected to the source of transistor 602. The drain of transistor 600 is connected to the gate and drain of 604. The gate of transistor 602 is connected to node 440. The drain of transistor 602 is connected to the gate and drain of 606. The gate of transistor 604 is attached to the gate of transistor 608. The gate of transistor 606 is connected to the gate of transistor 610. The drain of transistor 608 is connected to the gate and drain of transistor 612. The drain of transistor 610 is connector to the drain of transistor 614. The gate of 612 is connected to the gate of transistor 614. The source of transistor 612 is connected to supply voltage source 408. The drain of transistor 614 is connected to the gates of transistors 412 and 414 at node 448. The sources of transistors 604, 606. 608 and 610 are attached to a ground 618.

Transistors 600 and 602 are configured to act as inputs for a differential amplifier with 604 and 606 being loads and 614 as the output. Voltage at node 438 is fed to negative input of differential stage or to transistor 600. Voltage at node 440 is fed to the positive input of differential stage or to transistor 602. Current from transistor 600 creates a voltage at the gate of transistor 608 and 604. Current from transistor 602 creates a voltage at to the gate of transistor 606 and transistor 610. Transistors 604 and 606 make a current mirror with transistors 608 and 610, respectively. Current is then pulled to transistor 612 and mirrored back to transistor 614. The drain of transistor 614 is connected to node 448, which controls the gate voltage of transistors 412 and 414.

Differential amplifier 432 tries to hold nodes 438 and 440 to equal voltage.

The performance of circuit 400 will now be described with reference to FIGS. 7-9 and will be compared to conventional output current circuits.

Implementation results of circuit 400 will now be described with reference to FIG. 7. FIG. 7 shows a graph 700 of current and voltage across resistor 434 as functions of temperature. Graph 700 includes an x-axis 702, a left y-axis 704 and a right y-axis 706. X-axis 702 is temperature in degrees Celsius ranging from −40° Celsius to 160° Celsius. Left y-axis 704 is voltage in mV ranging from 223 mV to 229 mV. Right y-axis 706 is current in μA ranging from 4.92 μA to 5.1 μA, which is a ±1.8% variation.

Graph 700 includes a plot 708, a plot 710 and a plot 712. Plot 710 shows the change of voltage across resistor 434 as temperature increases, when an ideal constant current flows through it, which is nothing but the temperature coefficient of resistor 434. Plots 710 and 1112 show the actual results for circuit 400. Plot 712, which is read using left y-axis 704, shows the actual change in voltage across resistor 434 as temperature increases. Ideally plot 712 should be the same as plot 708. Plot 710, which is read using right y-axis 1106, shows the actual change in current through resistor 434 as temperature increases.

The performance of current across resistor 434 in circuit 400 with variation in process, voltage and temperature (PVT) will be shown using FIG. 8. Output current from output current port 420 is based on the current across resistor 434. One goal of the present invention is for the current across resistor 434 to remain constant.

FIG. 8 shows a graph 800 of current across resistor 434 as temperature increases in accordance with an aspect of the present invention. Graph 800 includes x-axis 802 and y-axis 804. X-axis 802 is temperature in degrees Celsius ranging from −30° Celsius to 130° Celsius. Y-axis 804 is current in μA ranging from 4.7 μA to 5.2 μA. Graph 800 includes plot 806 and plot 808, which represent 3σ performance of the current through resistor 434. A 3σ performance includes the variation in the process which includes all device components and variation in supply voltage 408. Plot 806 represents the positive 3σ performance of the current through resistor 434, whereas plot 808 represents the negative 3σ performance of the current through resistor 434.

Graph 800 represents the worst-case scenario in terms of current variation through resistor 434 across PVT. The nominal-case scenario in terms of current variation across resistor 434 as temperature varies will now be described with reference to and FIG. 9.

A comparison between the performance of current generating circuit 400 and a conventional current reference circuit of the prior art will now be discussed with reference to FIG. 9.

FIG. 9 shows a graph 900 of the output current of a conventional current reference circuit as temperature increases. Graph 900 includes x-axis 902 and y-axis 904. X-axis 902 is temperature in degrees Celsius ranging from −40° Celsius to 155° Celsius. Y-axis 904 is current in μA ranging from 21.0 μA to 24.0 μA, which is a ±6.9% variation.

Graph 900 includes a plot 906, which represents the performance of the conventional current reference circuit. Points 908 and 910 represent the lower and upper temperature bounds, 130° Celsius and 155° Celsius, respectively, that a resistor may encounter in a typical automotive environment. In the range represented between points 908 and 910, the additional change in the output current is 7.6%. In FIG. 7, plot 708 shows the output current only varying by 1.7% in that same temperature range.

As discussed above, in accordance with aspects of the present invention, a constant current generator having a low variation in output current at across wide temperature range, such as for circuits used in the automotive field, has four times tighter variation than conventional constant current generators. If the variation of the output current is high for the temperature range required by these circuits then the operation of the circuits may he unpredictable. In some cases the thermal run-away can cause a permanent device failure.

The embodiment circuit of FIG. 4 achieves 2.5% accuracy with 60-microwatt power consumption in an area of 45 nm. The FOM in this example equals to 0.18, which is significantly less than the prior art that was found to have an FOM ranging between 0.625 and 2.5.

Previous efforts to generate circuits having a constant current in a varied temperature environment were less accurate. With ever need higher precision circuits in electronic industry, there is a need for more accurate reference circuit and aspects in accordance with the present invention meet the requirements for next-generation electronic devices.

A circuit having more accurate output current with lower-supply voltage in a varying temperature environment is achieved via aspects of the present invention. Specifically, this is achieved by generating a fractional CTAT voltage, generating a PTAT voltage and summing these voltages as is shown in FIG. 3 and FIG. 4.

The exemplary embodiment circuit of FIG. 4 provides a current accuracy of 2.5% with a FOM of only 0.18. This is a vast improvement over prior efforts.

The foregoing description of various preferred embodiments of the invention have been presented for purposes of illustration and description. It is not intended to be exhaustive or to limit the invention to the precise forms disclosed, and obviously many modifications and variations are possible in light of the above teaching. The example embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed as new and desired to he protected by Letters Patent of the United States is:

1. A current generating circuit, said current generating circuit comprising:
a current mirror having a current output leg and a current generating leg, said current output leg being connected to said current generating leg;
an impedance device connected to said current generating leg;
a first voltage generating portion operable to generate a first voltage that is complementary to absolute temperature; and
a second voltage generating portion operable to generate a second voltage that is proportional to absolute temperature,
wherein the first voltage is based on an attenuation of a voltage drop across said impedance device.

2. The current generating circuit of claim 1,
wherein said impedance device has an impedance value, a first terminal and a second terminal,
wherein said first voltage generating portion is connected to said first terminal,
wherein said second voltage generating portion is connected to said first terminal,
wherein said first voltage generating portion and said second voltage generating portion are arranged to generate an impedance current across said impedance device,
wherein said current output leg is operable to output an output current based on the impedance current,
wherein the voltage drop across said impedance device comprises a voltage drop between said first terminal and said second terminal and is equal to a product of the impedance value and the impedance current, and
wherein said first voltage generating portion comprises an impedance divider.

3. The current generating circuit of claim 2, wherein said impedance divider comprises a first resistor and a second resistor.

4. The current generating circuit of claim 3, wherein said second voltage generating portion comprises a differential amplifier and a translinear loop having a transistor including a base.

5. The current generating circuit of claim 4, wherein said first resistor and said second resistor are connected to said base.

6. The current generating circuit of claim 5, wherein said first voltage generating portion further comprises a unity gain amplifier connected to said first resistor.

7. The current generating circuit of claim 4, wherein said first voltage generating portion further comprises a unity gain amplifier connected to said first resistor.

8. The current generating circuit of claim 7, wherein said impedance device comprises a resistor.

9. The current generating circuit of claim 8, wherein said resistor comprises a trimable resistor.

10. The current generating circuit of claim 8, wherein said resistor comprises a variable resistor.

11. The current generating circuit of claim 1, wherein said second voltage generating portion comprises a differential amplifier and a translinear loop having a transistor including a base.

12. The current generating circuit of claim 11, wherein said impedance device comprises a resistor.

13. The current generating circuit of claim 12, wherein said resistor comprises a trimable resistor.

14. The current generating circuit of claim 12, wherein said resistor comprises a variable resistor.

15. The current generating circuit of claim 1, wherein said impedance device comprises a resistor.

16. The current generating circuit of claim 15, wherein said resistor comprises a trimable resistor.

17. The current generating circuit of claim 15, wherein said resistor comprises a variable resistor.

18. A current generating circuit, said current generating circuit comprising:
a current mirror having a current output leg and a current generating leg;
a resistor connected to said current generating leg;
a first voltage generating portion operable to generate a first voltage that is complementary to absolute temperature, said first voltage generating portion comprising an impedance divider and a unity gain amplifier, said impedance divider comprising a first resistor and a second resistor, said unity gain amplifier being connected to said first resistor; and
a second voltage generating portion operable to generate a second voltage that is proportional to absolute temperature, said second voltage generating portion including a differential amplifier and a translinear loop having a transistor including a base,
wherein said first voltage generating portion and said second voltage generating portion are arranged to generate an impedance current across said impedance device,
wherein said current output leg is operable to output an output current based on said impedance current,
wherein said impedance device has an impedance value, a first terminal and a second terminal,
wherein an impedance voltage drop across said first terminal and said second terminal is equal to a product of the impedance value and the impedance current,
wherein the first voltage is based on an attenuation of the impedance voltage drop, and
wherein said first resistor and said second resistor are connected to said base.

19. A method of generating current, said method comprising:
generating, in a circuit having an impedance device, a current mirror a first voltage generating portion and a second voltage generating portion, the current mirror having a current output leg and a current generating leg, the current output leg being connected to the current generating leg, the impedance device being connected to the current generating leg, a first voltage, by way of the first voltage generating portion, that is complementary to absolute temperature; and
generating a second voltage, by way of the second voltage generating portion, that is proportional to absolute temperature,
wherein the first voltage is based on an attenuation of a voltage drop across the impedance device.

20. The method of claim 19,
wherein the impedance device has an impedance value, a first terminal and a second terminal,
wherein the first voltage generating portion is connected to the first terminal,
wherein the second voltage generating portion is connected to the first terminal,
wherein the first voltage generating portion and the second voltage generating portion are arranged to generate an impedance current across the impedance device,
wherein the current output leg is operable to output an output current based on the impedance current,
wherein the voltage drop across the impedance device comprises a voltage drop between the first terminal and the second terminal and is equal to a product of the impedance value and the impedance current, and
wherein said generating a first voltage, by way of the first voltage generating portion, that is complementary to absolute temperature comprises generating a first voltage by way of an the first voltage generating portion, which includes an impedance divider.
